(19) United States
(12) Patent Application Publication
(10) Pub. No.: US 2013/0344232 A1
(43) Pub. Date: Dec. 26, 2013

(54) METHODS OF FORMING CONDUCTIVE FEATURES ON THREE-DIMENSIONAL OBJECTS

(71) Applicants: Naveen CHOPRA, Oakville (CA); Yiliang WU, Oakville (CA); Ping LIU, Mississauga (CA); Barkev KEOSHKERIAN, Thornhill (CA); Michelle CHRETIEN, Mississauga (CA)

(72) Inventors: Naveen CHOPRA, Oakville (CA); Yiliang WU, Oakville (CA); Ping LIU, Mississauga (CA); Barkev KEOSHKERIAN, Thornhill (CA); Michelle CHRETIEN, Mississauga (CA)

(73) Assignee: XEROX CORPORATION, Norwalk, CT (US)

(21) Appl. No.: 13/530,861

(22) Filed: Jun. 22, 2012

(51) Int. Cl. H05K 3/00; H01G 13/00; B82Y 40/00

(52) U.S. Cl. 427/79; 427/98.4; 427/97.6; 977/932

(57) ABSTRACT

A method of forming a conductive feature on a three-dimensional object may include depositing a composition comprising nanoparticles onto a portion of the three-dimensional object, and annealing the composition to form the conductive feature. In another embodiment, a method of forming a conductive feature on a three-dimensional object may include printing a composition comprising nanoparticles to produce a contiguous line over a non-planar portion of the three-dimensional object, and heating the composition to form a conductive feature that has conductivity throughout.

### BACKGROUND

Electronic circuits are in wide-spread use and are composed of various components, including resistors, transistors, capacitors, inductors, and diodes. The components of electronic circuits have conductive portions and are connected by conductive wires (or conductive traces) through which electric current can flow. Simple to complex operations can be performed depending on the arrangement of the components and wires.

Currently, electronic circuits are commercially manufactured by applying photolithography techniques to a semiconductor substrate (such as a silicon substrate). Other manufacturing techniques have been proposed and are being sought. Of course, other manufacturing techniques must be able to form conductive features in order to form components and wires of electronic circuits.

### SUMMARY

Conductive inks printable onto a substrate have been proposed. Printable conductive inks could offer promise for using deposition techniques, such as printing, for forming conductive features. However, various known or perceived drawbacks of conductive inks are in need of resolution to advance their use in forming useful conductive features, such as conductive features of components and wires of electronic circuits.

Conductive inks can be highly substrate dependent and, thus, can only be used in methods to form conductive features on smooth planar surfaces, such as polished silicon and glass planar surfaces. It is not expected that conductive inks can form non-planar conductive features on a three-dimensional object. Annealing temperatures of conductive inks can render the conductive inks unsuitable for use on plastic and polymer surfaces. Accordingly, there is a need to develop a method of forming a conductive feature that reduces drawbacks of methods using previously proposed conductive inks.

In view of the above, a method of forming a conductive feature on a three-dimensional object may comprise depositing a composition comprising nanoparticles onto a portion of the three-dimensional object, and annealing the composition to form the conductive feature. In another embodiment, a method of forming a conductive feature on a three-dimensional object may comprise printing a composition comprising nanoparticles to produce a contiguous line over a non-planar portion of the three-dimensional object, and heating the composition to form a conductive feature that has conductivity throughout.

### BRIEF DESCRIPTION OF THE DRAWINGS

FIG. 1 depicts an exemplary method of forming a conductive feature on a three-dimensional object.

FIG. 2 depicts printed posts with conductive tips of varying heights.

FIG. 3 depicts a printed capacitor.

FIG. 4 is an image of a printed and annealed silver line on top of a UV-gel ink structure in both reflection and transmission modes.

FIG. 5 is an image of a silver line run over a UV-gel structure onto a substrate.

### EMBODIMENTS

A method of forming a conductive feature on a three-dimensional object may comprise depositing a composition comprising nanoparticles onto a portion of the three-dimensional object, and annealing the composition to form the conductive feature. The method may further comprise producing the three-dimensional object before depositing the composition, where the production of the three-dimensional object comprises depositing an object-forming composition to form layers on a portion of a substrate, and curing the object-forming composition.

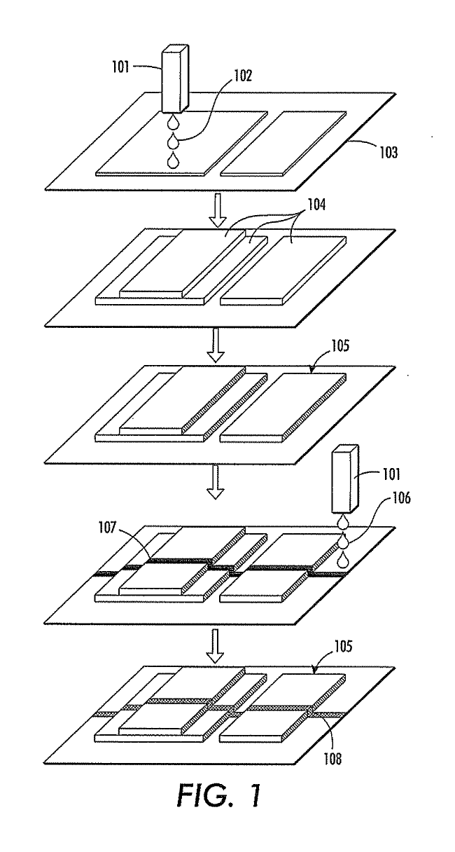

For illustration purposes only, FIG. 1 depicts an exemplary method of forming a conductive feature on a three-dimensional object. In FIG. 1, a print head 101 deposits an object-forming composition 102 onto portions of a substrate 103 to produce object-forming composition layers 104. The object-forming composition layers 104 are cured to produce a three-dimensional object 105. Then, the print head 101 deposits a composition comprising nanoparticles 106 onto the three-dimensional object 105 to form a line 107. The line 107 is annealed to form the conductive feature 108 onto the three-dimensional object 105.

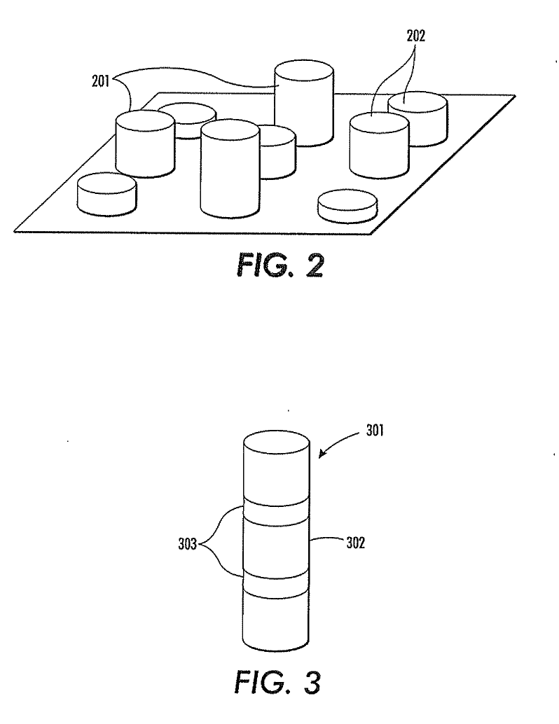

Also for illustration purposes only, FIG. 2 depicts printed posts 201 of varying heights and conductive tips 202 formed on the top of the printed posts 201. The printed posts 201 and conductive tips 202 can be formed by embodiments of the method for forming a conductive feature on a three-dimensional object. FIG. 3 depicts a capacitor 301 having insulting layers 302 and conductive layers 303 that can be formed by embodiments of the method for forming conductive features.

Embodiments of the method of forming conductive features are further discussed below.

Depositing Step

In embodiments, a method of forming a conductive feature on a three-dimensional object comprises depositing a composition comprising nanoparticles onto a portion of a three-dimensional object. Deposition may be performed by printing the composition onto the portion of the three-dimensional object. Printing may be performed by using any suitable printing system. Exemplary printing systems include ink jet printers, thermal transfer printers, gravure printers, electrostatographic systems, and the like. Although ink jet printers, as well as other printing systems, are typically contemplated for jetting ink, they can be used to jet other compositions that may or may not be considered to be “ink” depending on how broadly the term “ink” is applied to such compositions.

Ink jet printers are generally of two types: continuous stream and drop-on-demand. In continuous stream ink jet systems, a composition, such as ink, is emitted in a continuous stream under pressure through at least one orifice or nozzle. The stream is perturbed, causing it to break up into droplets at a fixed distance from the orifice. At the break-up point, the droplets are charged in accordance with digital data signals and passed through an electrostatic field that adjusts the trajectory of each droplet in order to direct it to a gutter for recirculation or to a specific location. In drop-on-demand systems, a droplet is expelled from an orifice directly to a position on a medium in accordance with digital data signals. A droplet is not formed or expelled unless it is to be placed on the medium. An example of a continuous stream inkjet system is an aerosol inkjet system.

There are generally three types of drop-on-demand ink jet systems. One type of drop-on-demand system is a piezoelectric device that has as its major components a composition-filled channel or passageway having a nozzle on one end and a piezoelectric transducer near the other end to produce pressure pulses. Another type of drop-on-demand system is known as acoustic ink printing. As is known, an acoustic beam exerts a radiation pressure against objects upon which it impinges. Thus, when an acoustic beam impinges on a free surface (that is, liquid/air interface) of a pool of liquid from beneath, the radiation pressure which it exerts against the surface of the pool may reach a sufficiently high level to release individual droplets of liquid from the pool, despite the restraining force of surface tension. Focusing the beam on or near the surface of the pool intensifies the radiation pressure it exerts for a given amount of input power. Still another type of drop-on-demand system is known as thermal ink jet, or bubble jet, and produces high velocity droplets. The major components of this type of drop-on-demand system are a composition-filled channel having a nozzle on one end and a heat generating resistor near the nozzle. Printing signals representing digital information originate an electric current pulse in a resistive layer within each passageway near the orifice or nozzle, causing a liquid vehicle (usually water) in the immediate vicinity to vaporize almost instantaneously and create a bubble. The composition at the orifice is forced out as a propelled droplet as the bubble expands.

The composition comprising nanoparticles may be deposited as a layer on a portion of a three-dimensional object. More than one layer may be deposited at the same and at different portions. Each layer may have a thickness of from about 0.0001 to about 6.0 mm, such as from 0.0005 to about 2.0 mm, or from about 0.001 to about 1.0 mm.

Annealing Step

In embodiments, a method of forming a conductive feature on a three-dimensional object further comprises annealing the composition comprising nanoparticles to form the conductive feature. Annealing may be performed by heating the composition comprising nanoparticles. Examples of heating techniques include thermal heating (for example, a hot plate, an oven, and a burner), infra-red radiation, a laser beam, microwave radiation, UV radiation, or a combination thereof.

Heating may be at a temperature of 250° C. or below. For instance, the composition comprising nanoparticles may be heated at a temperature of, for example, from about 80° C. to about 250° C., from about 100° C. to about 200° C., from about 120° C. to about 180° C., or from about 120° C. to about 150° C. A two-stage heating process can also be used where the temperature of the first stage heating is lower than the second stage heating and the first stage heating enables partial annealing. The heating temperature is one that does not cause adverse changes in the properties of the three-dimensional object. Thus, the heating temperature may be below 150° C. to avoid adverse changes in the three-dimensional object, where the three-dimensional object is made from a material that is designed for annealing at low-temperature. In embodiments, the heating temperature may be below 120° C.

The heating may be performed for a time ranging from, for example, 1 second to about 10 hours and from about 10 seconds to 1 hour. The heating may be performed in air, in an inert atmosphere, for example, under nitrogen or argon, or in a reducing atmosphere, for example, under nitrogen containing from 1 to about 20 percent by volume hydrogen. The heating may also be performed under normal atmospheric pressure or at a reduced pressure of, for example, from about 1000 mbars to about 0.01 mbars.

Heating produces a number of effects. Prior to heating, the layer of the deposited nanoparticles may be electrically insulating or with very low electrical conductivity, but heating results in an electrically conductive layer composed of annealed nanoparticles, which increases the conductivity. In embodiments, the annealed nanoparticles may be coalesced or partially coalesced nanoparticles. In other embodiments, after heating, the annealed nanoparticles may achieve sufficient particle-to-particle contact to form the electrically conductive feature without coalescence.

Composition Comprising Nanoparticles

The composition for forming the conductive feature comprises nanoparticles. In embodiments, the composition comprises nanoparticles, an optional phase-change agent, an optional low-melting wax, and a dispersing solvent. The composition may further comprise other additives, such as an antioxidant, a leveling agent, an adhesive additive, etc. The nanoparticles may be stabilized with ligands or stablizers. The stabilized nanoparticles may be stabilized silver nanoparticles.

Nanoparticles

The nanoparticles have a particle size of less than about 1,000 nm, such as, for example, from about 0.5 nm to about 1,000 nm, from about 1 nm to about 500 nm, from about 1 nm to about 100 nm, from about 1 nm to about 25 nm or from about 5 nm to about 25 nm. The particle size refers to the average diameter of the metal particles, as determined by TEM (transmission electron microscopy) or other suitable methods.

In embodiments, the nanoparticles may be metal nanoparticles, including silver nanoparticles. The silver nanoparticles may comprise (i) one or more metals in addition to silver or (ii) one or more metal composites that include silver. Suitable additional metals include, for example, Al, Au, Pt, Pd, Cu, Co, Cr, In, and Ni, particularly the transition metals, for example, Au, Pt, Pd, Cu, Cr, Ni, and mixtures thereof. Suitable metal composites include Au—Ag, Ag—Cu, Ag—Ni, Au—Ag—Cu, and Au—Ag—Pd. The silver composites may include non-metals, such as, for example, Si, C, and Ge. The various components of the silver composite may be present in an amount ranging for example from about 0.01% to about 99.9% by weight, particularly from about 10% to about 90% by weight. In embodiments, the silver composite is an alloy composed of silver and one, two or more other metals, with silver comprising for example at least about 20% of the nanoparticles by weight, particularly greater than about 50% of the nanoparticles by weight. The recited weight percentages do not include the weight of any stabilizer.

The silver nanoparticles may be a mixture of two or more bimetallic metal nanoparticle species, such as those described in U.S. Patent Application Publication No. 2009/0274834, which is incorporated herein by reference in its entirety, or a bimodal metal nanoparticle, such as those described in U.S. Pat. No. 7,749,300, which is also herein incorporated by reference in its entirety.

Stabilized Nanoparticles

The nanoparticles may have an organic stabilizer connected to the surface of the nanoparticles and is not removed in part or in full until the annealing of the nanoparticles during formation of the conductive features on the three-dimensional object. The nanoparticles, such as silver nanoparticles, may be physically or chemically associated with the organic stabilizer, such that the stabilizer can be chemically bonded or otherwise physically attached to the nanoparticles. The chemical bond may take the form of covalent bonding, hydrogen bonding, coordination complex bonding, ionic bonding, or a mixture of different chemical bonds. The physical attachment may take the form of van der Waals' forces, dipole-dipole interaction, or a mixture of different physical attachments.

The organic stabilizer contains carbon atoms, but may also include one or more non-metal heteroatoms, such as nitrogen, oxygen, sulfur, silicon, halogen, and the like. The organic stabilizer may be an organoamine stabilizer such as those describe in U.S. Pat. No. 7,270,694, which is incorporated by reference herein in its entirety. Examples of the organoamine include an alkylamine, such as methylamine, ethylamine, propylamine, butylamine, pentylamine, hexylamine, heptylamine, octylamine, nonylamine, decylamine, hexadecylamine, undecylamine, dodecylamine, tridecylamine, tetradecylamine, diaminopentane, diaminohexane, diaminoheptane, diaminooctane, diaminononane, diaminodecane, diaminooctane, dipropylamine, dibutylamine, dipentylamine, dihexylamine, diheptylamine, dibutylamine, dinonylamine, didecylamine, methylpropylamine, ethylpropylamine, propylbutylamine, ethylbutylamine, ethylpentylamine, propylpentylamine, butylpentylamine, tributylamine, trihexylamine, and mixtures thereof. In embodiments, the stabilized nanoparticles are organoamine-stabilized nanoparticles.

Examples of other organic stabilizers include, for example, thiol and its derivatives, —OC(═S)SH (xanthic acid), polyethylene glycols, polyvinylpyridine, polyvinylpyrolidone, and other organic surfactants. The organic stabilizer may be selected from the group consisting of a thiol such as, for example, butanethiol, pentanethiol, hexanethiol, heptanethiol, octanethiol, decanethiol, and dodecanethiol; a dithiol such as, for example, 1,2-ethanedithiol, 1,3-propanedithiol, and 1,4-butanedithiol; or a mixture of a thiol and a dithiol. The organic stabilizer may be selected from the group consisting of a xanthic acid such as, for example, O-methylxanthate, O-ethylxanthate, O-propylxanthic acid, O-butylxanthic acid, O-pentylxanthic acid, O-hexylxanthic acid, O-heptylxanthic acid, O-oetylxanthic acid, O-nonylxanthic acid, O-decylxanthic acid, O-undecylxanthic acid, O-dodecylxanthic acid. Organic stabilizers containing a pyridine derivative (for example, dodecyl pyridine) and/or organophosphine that can stabilize nanoparticles can also be used as a potential stabilizer.

Further examples of organic stabilizers may include: the carboxylic acid-organoamine complex stabilized metal nanoparticles, described in U.S. Patent Application Publication No. 2009/0148600; the carboxylic acid stabilizer metal nanoparticles described in U.S. Patent Application Publication No. 2007/0099357; and the thermally removable stabilizer and the UV decomposable stabilizers described in U.S. Patent Application No. 2009/0181183, each of which are incorporated by reference herein in their entirety.

The extent of the coverage of stabilizer on the surface of the nanoparticles can vary, for example, from partial to full coverage depending on the capability of the stabilizer to stabilize the nanoparticles. Of course, there is variability as well in the extent of coverage of the stabilizer among the individual nanoparticles.

Phase-Change Agent

The composition may include a gellant and/or a wax as the phase-change agent. The inclusion of a phase-change agent allows the compositions to “phase change” or undergo a sharp increase in viscosity over a narrow temperature range upon cooling the composition to a temperature above room temperature, and harden to a gel-like consistency, which is retained as the compositions are cooled further to room temperature. For example, the composition may have a viscosity which changes by a factor of about 10² to about 10⁹ over a temperature change of only about 10° C. to about 50° C. In embodiments, the inclusion of a phase-change agent in the composition may result in a change in viscosity of at least about 10² centipoise (cP), for example, from about 10³ cP to about 10⁷ cP and from about 10³ cP to about 10⁶ cP over a temperature range of, for example, at least about 20° C., for example, from about 40° C. to about 120° C., from about 60° C. to about 100° C. or from about 70° C. to about 95° C.

In embodiments, a gellant is used as the phase-change agent. Various compositions containing gellants are described in U.S. Pat. Nos. 6,906,118, 6,761,758, 6,811,595, 6,860,928, and 6,872,243, the disclosures of which are incorporated herein in their entirety by reference. The gellant compositions disclosed herein can affect the viscosity of the composition within a desired temperature range. In particular, the gellant may form a semi-solid gel in the composition at temperatures below the specific temperature at which the composition is deposited.

The semi-solid gel phase is a physical gel that exists as a dynamic equilibrium comprising one or more solid gellant molecules and a liquid solvent. The semi-solid gel phase is a dynamic networked assembly of molecular components held together by non-covalent interactions such as hydrogen bonding, Van der Waals interactions, aromatic non-bonding interactions, ionic or coordination bonding, London dispersion forces, or the like, which, upon stimulation by physical forces, such as temperature, mechanical agitation, or the like, can undergo reversible transitions from liquid to semi-solid state at the macroscopic level. The solutions containing the gellant molecules exhibit a thermally reversible transition between the semi-solid gel state and the liquid state when the temperature is varied above or below the gel point of the solution. This reversible cycle of transitioning between semi-solid gel phase and liquid phase can be repeated many times in the solution formulation.

In a further embodiment, adding a gellant or a mixture of gellants can modify the rheological profile of the composition often recognized by the presence of one or more viscosity plateaus at temperatures above room temperature. This can be described as the gel state. In this state, the gelled compositions exhibit visco-elastic rheological characteristics that are different from those of conventional hot melt or phase-change compositions in that they show an elastic behavior in a temperature region where the composition is supposed to be in the liquid state. The gel state can have a gel point, associated with the onset of gelation upon cooling. The gel point is evidenced by the crossover of G′ (storage modulus) and G″ (loss modulus), with G′ being higher than G″, indicating that the material is elastic. When more than one gellant is used in the gellant composition, it is expected that the viscosity in the plateau region of the first gellant is at least one order of magnitude lower than the viscosity in the second plateau region. Optionally, the compositions may contain a mixture of more than one gellants, wherein the gellants may be selected from the amorphous or crystalline types.

Upon cooling, gelation can occur before room temperature or before the temperature of the substrate onto which the gel composition is deposited or coated. The “gel point” temperature in one embodiment is equal to or less than about 95° C., in another embodiment equal to or less than about 90° C., and in a further embodiment equal to or less than about 85° C. If more than one gel transition is enabled by the use of more than one gellant, the first “gel point” can be from about 5° C. to about 60° C. below the subsequent transition. In some applications, it might be necessary to overlap the transitions, as a result the viscosity plateaus will not be apparent.

In embodiments, the temperature at which the composition forms the gel state is any temperature below the depositing temperature of the composition, for example, any temperature that is about 5° C. or more below the depositing temperature of the composition. In embodiments, the gel state may be formed at temperatures in one embodiment from about 25° C. to about 100° C., in another embodiment from about 30° C. to about 70° C., and in yet another embodiment from about 30° C. to about 50° C. There is a rapid and large increase in viscosity upon cooling from the depositing temperature at which the composition is in a liquid state, to the gel transition temperature, at which the composition converts to the gel state. The viscosity increase is in one embodiment at least a 10¹⁵-fold increase in viscosity.

When the compositions described herein are in the gel state, the viscosity of the composition is in one embodiment at least about 1,000 cP, in another embodiment at least about 10,000 cP, and in yet another embodiment at least about 100,000 cP. Viscosity values in the gel state are in the range of in one embodiment from about 10³ to about 10⁹ cP, and in another embodiment from about 10⁴⁵ to about 10^{6.5} cP.

Exemplary gellants are discussed below with respect to the object-forming composition.

Low-Melting Wax

The composition may also comprise one or more low-melting waxes. The low-melting wax may be at least about 0.1% by weight of the composition (exclusive of solvent). In embodiments, the low-melting may comprise at least about 1% by weight of the composition, at least about 5% by weight of the composition, equal to or less than about 20% by weight of the composition, equal to or less than about 35% by weight of the composition, and/or equal to or less than about 25% by weight of the composition (exclusive of solvent).

The low-melting wax may be a polyalkylene wax, such as a polyethylene wax, a polypropylene wax, mixtures thereof, or the like. Examples of suitable polyalkylene waxes include POLYWAX 500 (commercially available from Baker Petrolite) and distilled POLYWAX 500, in one embodiment having a viscosity at a depositing temperature of about 110° C. of about 10% to about 100% higher than the viscosity of the undistilled POLYWAX 500, POLYWAX 400 commercially available from Baker Petrolite and distilled POLYWAX 400, VYBAR 103 and VYBAR 253 commercially available from Baker Petrolite, and POLYWAX 655. Higher molecular weight POLYWAX materials may also suitable. The molecular weight of the polyalkylene wax may be in the range of 500 to 600 g/mole.

The low-melting wax component may comprise one or more functional waxes. In embodiments, the composition may comprise one or more functional alcohol waxes. The functional alcohol wax may be a mono-functional alcohol wax, a di-functional alcohol wax, a tri-functional alcohol wax, a tetra-functional alcohol wax, or mixtures thereof. The functional wax may be at least about 0.1% by weight of the composition, at least about 1% by weight of the composition, at least about 5% by weight of the composition, equal to or less than about 20% by weight of the composition, equal to or less than about 25% by weight of the composition, and/or equal to or less than about 35% by weight of the composition (exclusive of solvent).

In embodiments, at least a portion of the functional waxes can be mono-functional wax, which can be substituted with a di-, tri- and/or tetra-functional wax. The substitution may be done in one embodiment at a predetermined hydroxyl number for the resultant composition. The hydroxyl number (ASTM E-222-00 mod.) of the composition may be at least about 20, at least about 25, at least about 35, equal to or less than about 100, equal to or less than about 80, and/or equal to or less than about 50. In embodiments, the functional wax may have a melting temperature of at least about 50° C., at least about 60° C., at least about 70° C., equal to or less than about 110° C., equal to or less than about 105° C., and/or equal to or less than about 100° C.

Examples of suitable functional waxes include UNILIN 350 and UNILIN 425 (commercially available from Baker Petrolite), and the distilled fractions of these functional waxes. In embodiments, the viscosity of the distilled functional wax at the depositing temperature is from about 5 to equal to or less than about 50% higher than the non distilled functional wax(es). Other examples of functional wages are a 1-docosanol wax commercially available from Aldrich. Mono-functional waxes include waxes of 1-tetradecanol, 1-pentadecanol, 1-hexadecanol, 1-heptadecanol, 1-octadecanol, 1-nonadecanol, 1-eicosanol, 1-tricosanol, 1-tetracosanol, 1-pentacosanol, 1-hexacosanol, 1-heptacosanol, 1-octacosanol, 1-nonacosanol, 1-tricontanol, 1-dotriacontanol, 1-tritriacontanol, 1-tetratriacontanol. Guerbet alcohols can also be suitable such as 2-tetradecyl 1-octadecanol, 2-hexadecyl 1-eicosanol, 2-octadecyl 1-docosanol, 2-nonadecyl 1-tricosanol, 2-eicosyl tetracosanol, and mixtures thereof. Di-functional waxes include the waxes of diols such as 1,8-octanediol, 1,9-nonanediol, 1,10-decanediol, 1,12-dodecanediol, 1,13-tridecanediol, 1,14-tetradecanediol, 1,15-pentadecanediol, 1,16-hexandecanediol, 1,17-heptadecanediol, 1,18-octadecanediol, 1,19-nonadecanediol, 1,20-eicosanediol, 1,22-docosanediol, 1,25-pentacosanediol, and mixtures thereof. Other polyhydric alcohols that may be used in the composition are trimethylolpropane, pentaerythritol, neopentylglycol, mannitol, sorbitol, and mixtures thereof, including mixtures with mono- and di-functionalized alcohols above.

In embodiments, the weight ratio of the polyalkylene wax to functional wax may be at least about 035, at least about 0.40, at least about 0.45, equal to or less than to 0.65, equal to or less than about 0.60, and/or equal to or less than about 0.55.

Dispersing Solvent

The composition may comprise one or more dispersing solvents. The nanoparticles, phase-change agent, and optional low-melting wax may be provided to any suitable dispersing solvent in forming the composition for forming a conductive feature on the three-dimensional object. The weight percentage of the nanoparticles in the solvent may be at least about 20 weight percent of the total composition (inclusive of solvent), such as, for example, from about 20 to about 90 weight percent, or from about 35 to about 85 weight percent of the total composition.

The dispersing solvent should facilitate the dispersion of the nanoparticles, such as stabilized silver nanoparticles, and the phase-change agent, such as a gellant. Examples of the dispersing solvent may include, an alkane or an alcohol having from about 10 to about 18 carbon atoms, from about 10 to about 14 carbon atoms, or from about 10 to 12 carbon atoms, such as, undecane, dodecane, tridecane, tetradecane, 1-undecanol, 2-undecanol, 3-undecanol, 4-undecanol, 5-undecanol, 6-undecanol, 1-dodecanol, 2-dodecanol, 3-dodecanol, 4-dodecanol, 5-dodecanol, 6-dodecanol, 1-tridecanol, 2-tridecanol, 3-tridecanol, 4-tridecanol, 5-tridecanol, 6-tridecanol, 7-tridecanol, 1-tetradecanol, 2-tetradecanol, 3-tetradecanol, 4-tetradecanol, 5-tetradecanol, 6-tetradecanol, 7-tetradecanol, and the like; isoparaffinic hydrocarbons, such as, for example, isodecane, isododecane, and commercially available mixtures of isoparaffins such as ISOPAR E, ISOPAR G, ISOPAR H, ISOPAR L and ISOPAR M (all the above-mentioned manufactured by Exxon Chemical Company), SHELLSOL (made by Shell Chemical Company), SOLTROL (made by Philips Oil Co., Ltd.), BEGASOL (made by Mobil Petroleum Co., Inc.) and IP Solvent 2835 (made by Idemitsu Petrochemical Co., Ltd.); mineral oil, tetrahydrofuran; chlorobenzene; dichlorobenzene; trichlorobenzene; nitrobenzene; cyanobenzene; acetonitrile; dichloromethane; N,N-dimethylformamide (DMF); aromatic hydrocarbons such as toluene, xylene, trimethylbenzene, ethylbenzene, tetrahydronaphthalene; decalin; and mixtures thereof. One, two, three or more solvents may be used. In embodiments where two or more solvents are used, each solvent may be present at any suitable volume ratio or molar ratio such as for example from about 99(first solvent):1(second solvent) to about 1(first solvent):99(second solvent) or from about 80(first solvent):20(second solvent) to about 20(first solvent):80(second solvent).

The solvent may be present in the composition in an amount of at least 10 weight percent of the composition, such as for example from about 10 weight percent to about 80 weight percent, from about 20 weight percent to about 65 weight percent, from about 35 weight percent to about 60 weight percent and from about 40 weight percent to about 55 weight percent of the composition.

The composition may further comprise a monoterpene alcohol. Examples of the monoterpene alcohol may include terpineol (α-terpineol), β-terpineol, geraniol, cineol, cedral, linalool, 4-terpineol, lavandulol, citronellol, nerol, methol, borneol, and the like. The monoterpene alcohol may be present in the composition in an amount of about 1 weight percent to about 15 weight percent, from about 2 weight percent to about 12 weight percent, from about 5 weight percent to about 10 weight percent and/or from about 7 weight percent to about 10 weight percent of the composition.

The solution containing the nanoparticles and the phase-change agent may be optionally heated to a temperature of about at least 120° C., such as, for example, from about 120° C. to about 165° C., from about 125° C. to about 155° C., and from about 130° C. to about 145° C., for about 20 minutes to about 1 hour to accelerate the dissolution of the phase-change agent in the solution.

Antioxidant

The composition may comprise one or more antioxidants. Specific examples of suitable antioxidant stabilizers include NAUGARD® 524, NAUGARD® 635, NAUGARD® A, NAUGARD® 1-403, and NAUGARD® 959, commercially available from Crompton Corporation, Middlebury, Conn.; IRGANOX® 1010 and IRGASTAB® UV 10, commercially available from Ciba Specialty Chemicals; GENORAD 16 and GENORAD 40 commercially available from Rahn AG, Zurich, Switzerland, and the like, as well as mixtures thereof. The optional antioxidant may be present in an amount from about 0.01 to about 20%, such as about 0.1 to about 10%, or about 1 to about 5%, by weight of the composition (exclusive of solvent).

Three-Dimensional Object

The three-dimensional object is an object that can be used as a substrate on which a composition comprising nanoparticles may be deposited to form a conductive feature when annealed. A three-dimensional object is different from a planar substrate. Planar substrates are substrates that have a single planar surface for the deposition of a composition and, thus, the surface has a two-dimensional quality (although three-dimensional in the technical sense of the term). Planar substrates include, for example, plastic films, glass plates, silicon wafers, paper or transparency sheets, and fabrics. In contrast, three-dimensional objects have surfaces that have elevated and/or depressed portions by design, which are more pronounced than irregularities that exist in the surfaces of planar substrates. Accordingly, a three-dimensional object has an overall surface formed from surface portions that are at more than one plane. Three-dimensional objects may be formed using a planar substrate on which raised or depressed surface portions are formed. A three-dimensional object can be referred to as a “non-planar” or “a non-planar substrate” in the sense that a three-dimensional object is different from a planar substrate.

In embodiments, the three-dimensional object may have both rigid and rubbery components. For example, one component may be printed by using an object-forming composition that imparts a lower or higher room temperature modulus than another object-forming composition used to produce the three-dimensional object.

Conductive Feature

The conductive feature may vary in height as a result of the composition comprising nanoparticles being deposited on a portion of the three-dimensional object of varying heights and may have conductivity throughout the conductive feature. The conductive feature having conductivity throughout may be formed from depositing the composition comprising nanoparticles as a contiguous line over a portion of the three-dimensional object that is non-planar and annealing the composition. The three-dimensional object may have a plurality of conductive features formed thereon.

In embodiments, after annealing, the resulting electrically conductive feature has a thickness ranging, for example, from about 5 nanometers to about 50 microns and from about 10 nanometers to about 20 microns. The conductivity of the conductive feature is, for example, more than about 10 Siemens/centimeter (“S/cm”), more than about 1000 S/cm, more than about 2,000 S/cm, more than about 5,000 S/cm, or more than about 10,000 S/cm. The conductive feature may have a resistance of from 2 to 10,000 ohms.

The conductive feature may be components and wires of electronic circuits. The conductive feature is at least a portion of a conductive line, a conductive trace, a conductive via, a conductive pad, an electrode, or a capacitor. The conductive feature may be used as electrodes, conductive pads, thin-film transistors, conductive lines, conductive tracks, and the like in electronic devices such as thin film transistors, organic light emitting diodes, RFID (radio frequency identification) tags, photovoltaics, printed antenna and other electronic devices which require conductive elements or components.

Production of the Three-Dimensional Object

The production of the three-dimensional object may comprise depositing an object-forming composition to form layers on portions of a substrate, and curing the object-forming composition. Deposition may be performed by printing the object-forming composition onto a substrate. Printing may be performed by using any suitable printing system. Exemplary printing systems include ink jet printers, thermal transfer printers, gravure printers, electrostatographic systems, and the like.

For example, an ink jet printing apparatus that includes at least an ink jet print head and a print region surface toward which a composition is jetted from the ink jet print head, wherein a height distance between the ink jet print head and the print region surface is adjustable. Therein, the ink jet print head is adjustable in spacing with respect to the print region surface so as to permit the ink jet print head to be moved from a first position to a second height distance that is greater than (that is, the spacing between the ink jet print head and the print region surface is greater than) the first height distance. The second height distance is not fixed, and may be varied as necessary for a given printing. Moreover, the second height distance may itself be changed during a printing, as necessary. For example, it may be desirable to adjust the height distance from the first position to a second position as an object is built-up by the ink jet print head, and then as the object continues to be built-up, to adjust the ink jet print head from the second position to a third position in which the spacing from the print region surface is even further increased, and so on as necessary to complete build-up of the object.

In embodiments, the ink jet print head or target stage may be movable in three dimensions, x, y, and z, enabling the build up of an object of any desired size. Moreover, three-dimensional objects may be formed with appropriate multiple passing of the ink jet print head over an area to achieve the desired object height and geometry. Jetting of the object-forming composition from multiple different ink jets of the ink jet print head toward a same location of the image during a single pass may also be used to form the three-dimensional object.

A controller may then control the ink jet print head to deposit the appropriate amount and/or layers of the object-forming composition at locations of the image so as to obtain the object and overall geometries therein.

Any suitable substrate may be used to form the three-dimensional object thereon. Examples of suitable substrates include waxes, plastics, metals, wood, and glass, among others. The substrate may be planar. In embodiments, the three-dimensional object may be produced to be a free-standing object. That is, the substrate used to produce the three-dimensional object may be removed after the three-dimensional object is produced on the substrate.

In embodiments, the object-forming composition jetted at low temperatures, in particular at temperatures below about 110° C., such as from about 40° C. to about 110° C., or from about 50° C. to about 110° C., or from about 60° C. to about 90° C.

In embodiments, successive layers of the object-forming composition may be deposited to form an object having a selected height and shape. For example, objects of from about 1 to about 10,000 micrometers in height. The successive layers of the object-forming composition may be deposited to a build platform or to a previous layer of solidified material in order to build up a three-dimensional object in a layer-wise fashion. In embodiments, objects of virtually any design may be created, from a micro-sized scale to a macro-sized scale and may include simple objects to objects having complex geometries. The object-forming composition and method herein further advantageously provide a non-contact, additive process (as opposed to subtractive process such as computer numerical control machining) providing the built-in ability to deliver metered amounts of the object-forming composition to a precise location in time and space.

The object-forming composition is deposited to form a layer having a thickness from about 0.02 to about 6 mm, such as a thickness from 0.02 to 1.0 mm or from 0.10 to 0.80 mm. Successive layers may be formed to build the three-dimensional object.

In embodiments, the object-forming composition may be cured after each layer is deposited. In other embodiments, the object-forming composition may be cured upon completion of deposition of all layers of the three-dimensional object. The printed layers with the thickness of about 0.02 to about 6 mm, as described above, reduces the curing steps required to build a mechanically stable object, and further reduces the need to cure each layer after each deposition.

Curing of the object-forming composition may be performed by exposure of the composition to actinic radiation at any desired or effective wavelength. For example, the wavelength may be about 200 to about 480 nanometers. Exposure to actinic radiation may be for any desired or effective period of time. For example, the exposure may occur for about 0.2 to about 30 seconds, such as about 1 to about 15 seconds.

Object-Forming Composition

The object-forming composition may comprise a monomer, a photoinitiator, a wax and a phase-change agent, such as a gellant. Thus, the object-forming composition may be a phase-change composition. The object-forming composition may further comprise additives, such as the antioxidant discussed above with respect to the nanoparticle composition. In embodiments, the object-forming composition used for producing the three-dimensional object may have a room temperature modulus of from about 0.01 to about 5 GPa. In embodiments, the object-forming composition may be a set of object-forming compositions where each composition imparts a different room temperature modulus range. In embodiments, the object-forming composition set may comprise a first composition and at least one other composition where each composition has a different room temperature modulus between from about 0.01 to about 5 GPa. For example, the object-forming composition set may comprise a first composition having a room temperature modulus of from about 0.01 to about 2.5 GPa, such as from about 0.01 to about 1.25 or from about 1.25 to about 2.5 GPa, and a second composition having a room temperature modulus of from about 2.5 to about 5 GPa, such as from about 2.5 to about 3.75 GPa or from about 3.75 to about 5 GPa.

The object-forming composition set may comprise a first composition having a room temperature modulus of from about 0.01 to about 1.7 GPa, such as from about 0.01 to about 0.9 or from about 0.9 to about 1.7, a second composition having a room temperature modulus of from about 1.7 to about 3.4 GPa, such as from about 1.7 to about 2.6 GPa or from 2.6 to about 3.4 GPa, and a third composition having a room temperature modulus of from about 3.4 to about 5 GPa, such as from about 3.4 to about 4.3 or from about 4.3 to about 5 GPa. In embodiments, the object-forming composition set may comprise from 2 to 10 different object-forming compositions, such as from 3 to 8, or 4 to 6, or 2 to 4, or 5 to 9 different object-forming compositions.

Monomer

The object-forming composition may comprise one or more monomers. Suitable monomers include radiation curable monomer compounds, such as acrylate and methacrylate monomer compounds. Examples of monomers include propoxylated neopentyl glycol diacrylate (such as SR-9003 from Sartomer), diethylene glycol diacrylate, triethylene glycol diacrylate, hexanediol diacrylate, dipropyleneglycol diacrylate, tripropylene glycol diacrylate, alkoxylated neopentyl glycol diacrylate, isodecyl acrylate, tridecyl acrylate, isobornyl acrylate, isobornyl(meth)acrylate, propoxylated trimethylolpropane triacrylate, ethoxylated trimethylolpropane triacrylate, di-trimethylolpropane tetraacrylate, dipentaerythritol pentaacrylate, ethoxylated pentaerythritol tetraacrylate, propoxylated glycerol triacrylate, isobornyl methacrylate, lauryl acrylate, lauryl methacrylate, neopentyl glycol propoxylate methylether monoacrylate, isodecylmethacrylate, caprolactone acrylate, 2-phenoxyethyl acrylate, isooctylacrylate, isooctylmethacrylate mixtures thereof and the like. As relatively non-polar monomers, mention may be made of isodecyl(meth)acrylate, caprolactone acrylate, 2-phenoxyethyl acrylate, isooctyl(meth)acrylate, and butyl acrylate. In addition, multifunctional acrylate monomers/oligomers may be used not only as reactive diluents, but also as materials that can increase the cross-link density of the cured composition, thereby enhancing the toughness of the cured composition.

In embodiments, the monomer may be selected from the group consisting of acrylic monomer, polybutadiene adducted with maleic anhydride, aliphatic urethane acrylate, polyester acrylate, 3-acryloxypropyltrimethoxysilane, and acryloxypropyl t-structured siloxane, or a mixture thereof. Other exemplary monomers include any monomer listed in Sartomer's product listing under “monofunctional monomers” (available at www.sartomer.com/prodsubgroup.asp?plid=1&sgid=2).

In embodiments, the composition may comprise the monomer in an amount of from about 15% to about 60% by weight of the composition, such as from about 20% to about 55% or from about 25% to about 50% by weight. In other embodiments, the composition may comprise the monomer in an amount of from about 15% to about 35% by weight of the composition or from about 40% to about 60% by weight of the composition.

In embodiments, the monomers described above may impart a room temperature modulus of from about 0.01 to about 5 GPa, such as from about 0.51 to about 4.5 GPa, from about 1.01 to about 4 GPa, from about 1.51 to about 3.5 GPa, or from about 2.01 to about 3 GPa. The room temperature modulus may also be from about 0.01 to about 1.7 GPa, from about 1.7 to about 3.4 GPa, or from about 3.4 to about 5 GPa.

In embodiments, multifunctional acrylate and methacrylate monomers and oligomers may be included in the object-forming composition as reactive diluents and as materials that can increase the crosslink density of the cured composition, thereby enhancing the toughness of the cured composition. Different monomer and oligomers may also be added to tune the plasticity or elasticity of the cured composition. Examples of suitable multifunctional acrylate and methacrylate monomers and oligomers include pentaerythritol tetraacrylate, pentaerythritol tetramethacrylate, 1,2-ethylene glycol diacrylate, 1,2-ethylene glycol dimethacrylate, 1,6-hexanediol diacrylate (available from Sartomer Co. Inc. as SR238), 1,6-hexanediol dimethacrylate, 1,12-dodecanol diacrylate, 1,12-dodecanol dimethacrylate, tris(2-hydroxy ethyl)isocyanurate triacrylate, propoxylated neopentyl glycol diacrylate (available from Sartomer Co. Inc. as SR 9003), neopentyl glycol diacrylate esters (available from Sartomer Co. Inc. as SR247), 1,4-butanediol diacrylate (BDDA, available from Sartomer Co. Inc. as SR213), tripropylene glycol diacrylate, dipropylene glycol diacrylate, dioxane glycol diacrylate (DOGDA, available from Sartomer Co. In. as CD536), amine modified polyether acrylates (available as PO 83 F, LR 8869, and/or LR 8889 (all available from BASF Corporation), trimethylolpropane triacrylate, ethoxylated trimethylolpropane triacrylate (available from Sartomer Co. Inc. as SR454), glycerol propoxylate triacrylate, dipentaerythritol pentaacrylate, dipentaerythritol hexaacrylate, ethoxylated pentaerythritol tetraacrylate (available from Sartomer Co. Inc. as SR 494), and the like, as well as mixtures and combinations thereof.

Photoinitiator

The object-forming composition may comprise one or more photoinitiators. A photoinitiator that absorbs radiation, for example UV light radiation, to initiate curing of the curable components of the object-forming composition may be used. Object-forming compositions containing acrylate groups or object-forming compositions comprised of polyamides may include photoinitiators such as benzophenones, benzoin ethers, benzil ketals, α-hydroxyalkylphenones, α-alkoxyalkylphenones, α-aminoalkylphenones, and acylphosphine photoinitiators sold under the trade designations of IRGACURE and DAROCUR (available from BASF). Examples of suitable photoinitiators include 2,4,6-trimethylbenzoyldiphenylphosphine oxide (available as LUCIRIN TPO from BASF); 2,4,6-trimethylbenzoylethoxyphenylphosphine oxide (available as LUCIRIN TPO-L from BASF); bis(2,4,6-trimethylbenzoyl)-phenyl-phosphine oxide (available as IRGACURE 819 from BASF) and other acyl phosphines; 2-methyl-1-(4-methylthio)phenyl-2-(4-morphorlinyl)-1-propanone (available as IRGACURE 907 from BASF) and 1-(4-(2-hydroxyethoxy)phenyl)-2-hydroxy-2-methylpropan-1-one (available as IRGACURE 2959 from BASF); 2-benzyl 2-dimethylamino 1-(4-morpholinophenyl) butanone-1 (available as IRGACURE 369 from BASF); 2-hydroxy-1-(4-(4-(2-hydroxy-2-methylpropionyl)-benzyl)-phenyl)-2-methylpropan-1-one (available as IRGACURE 127 from BASF); 2-dimethylamino-2-(4-methylbenzyl)-1-(4-morpholin-4-ylphenyl)-butanone (available as IRGACURE 379 from BASF); titanocenes; isopropylthioxanthone (available as Darocur ITX from BASF); 1-hydroxy-cyclohexylphenylketone; benzophenone; 2,4,6-trimethylbenzophenone; 4-methylbenzophenone; 2,4,6-trimethylbenzoylphenylphosphinic acid ethyl ester; oligo(2-hydroxy-2-methyl-1-(4-(1-methylvinyl)phenyl)propanone); 2-hydroxy-2-methyl-1-phenyl-1-propanone; benzyl-dimethylketal; and mixtures thereof. Amine synergists may also be used. Amine synergists are co-initiators that donate a hydrogen atom to a photoinitiator and thereby form a radical species that initiates polymerization (amine synergists can also consume oxygen dissolved in the composition, as oxygen inhibits free-radical polymerization its consumption increases the speed of polymerization). Exemplary amine synergists include, for example, ethyl-4-dimethylaminobenzoate and 2-ethylhexyl-4-dimethylaminobenzoate.

The photoinitiator may absorb radiation of about 200 to about 420 nm wavelengths to initiate cure, although use of initiators that absorb at longer wavelengths, such as the titanocenes that may absorb up to 560 nm, may also be used.

The total amount of initiator included in the object-forming composition may be from, for example, about 0.5 to about 15 wt % by weight of the composition, such as from about 1 to about 10 wt %.

Reactive Wax

The object-forming composition may comprise one or more reactive waxes. In embodiments, the reactive wax may comprise a curable wax component that is miscible with the other components and that will polymerize with the curable monomer to form a polymer. Inclusion of the wax promotes an increase in viscosity of the composition as it cools from the jetting temperature.

Exemplary waxes include those that are functionalized with curable groups. In embodiments, the curable groups may include, acrylate, methacrylate, alkene, allylic ether, epoxide and oxetane. These waxes may be synthesized by the reaction of a wax equipped with a transformable functional group, such as carboxylic acid or hydroxyl.

Suitable examples of hydroxyl-terminated polyethylene waxes that may be functionalized with a curable group include, mixtures of carbon chains with the structure CH₃—(CH₂)ₙ—CH₂OH, where there is a mixture of chain lengths, n, where the average chain length is, in embodiments, in the range of about 16 to about 50, and linear low molecular weight polyethylene, of similar average chain length. Suitable examples of such waxes include, UNILIN® 350, UNILIN® 425, UNILIN® 550 and UNILIN® 700 with Mn approximately equal to 375, 460, 550 and 700 g/mol, respectively. All of these waxes are commercially available from Baker-Petrolite. Guerbet alcohols, characterized as 2,2-dialkyl-1-ethanols, are also suitable compounds. Specific embodiments of Guerbet alcohols include those containing 16 to 36 carbons, many of which are commercially available from Jarchem Industries Inc., Newark, N.J. In embodiments, PRIPOL® 2033 is selected, PRIPOL® 2033 being a C-36 dimer diol mixture including isomers of the formula

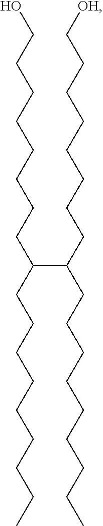 [SMILES: CCCCCCCCCC(CCCCCCCCO)C(CCCCCCCCC)CCCCCCCCO]

as well as other branched isomers which may include unsaturations and cyclic groups, available from Uniqema, New Castle, Del. Further information on C36 dimer diols of this type is disclosed in, for example, “Dimer Acids,” Kirk-Othmer Encyclopedia of Chemical Technology, Vol. 8, 4th Ed. (1992), pp. 223 to 237, the disclosure of which is totally incorporated herein by reference. These alcohols may be reacted with carboxylic acids equipped with UV curable moieties to form reactive esters. Examples of these acids include acrylic and methacrylic acids, available from Sigma-Aldrich Co. Specific curable monomers include acrylates of UNILINS 350, UNILIN® 425, UNILINO 550 and UNILIN® 700.

Suitable examples of carboxylic acid-terminated polyethylene waxes that may be functionalized with a curable group include mixtures of carbon chains with the structure CH₃—(CH₂)ₙ—COON, where there is a mixture of chain lengths, n, where the average chain length is in selected embodiments in the range of about 16 to about 50, and linear low molecular weight polyethylene, of similar average chain length. Suitable examples of such waxes include UNICID® 350, UNICID® 425, UNICID® 550 and UNICID® 700 with Mn equal to approximately 390, 475, 565 and 720 g/mol, respectively. Other suitable waxes have a structure CH₃—(CH₂)ₙ—COOH, such as hexadecanoic or palmitic acid with n=14, heptadecanoic or margaric or daturic acid with n=15, octadecanoic or stearic acid with n=16, eicosanoic or arachidic acid with n=18, docosanoic or behenic acid with n=20, tetracosanoic or lignoceric acid with n=22, hexacosanoic or cerotic acid with n=24, heptacosanoic or carboceric acid with n=25, octacosanoic or montanic acid with n=26, triacontanoic or melissic acid with n=28, dotriacontanoic or lacceroic acid with n=30, tritriacontanoic or ceromelissic or psyllic acid, with n=31, tetratriacontanoic or geddic acid with n=32, pentatriacontanoic or ceroplastic acid with n=33. Guerbet acids, characterized as 2,2-dialkyl ethanoic acids, are also suitable compounds. Selected Guerbet acids include those containing 16 to 36 carbons, many of which are commercially available from Jarchem Industries Inc., Newark, N.J. PRIPOL® 1009 (C-36 dimer acid mixture including isomers of the formula

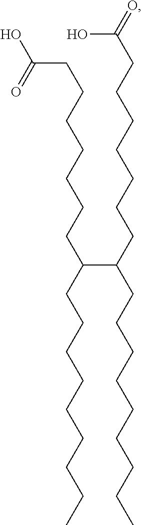 [SMILES: CCCCCCCCCC(CCCCCCCC(=O)O)C(CCCCCCCCC)CCCCCCCC(=O)O]

as well as other branched isomers which may include unsaturations and cyclic groups, available from Uniqema, New Castle, Del.; further information on C36 dimer acids of this type is disclosed in, for example, “Dimer Acids,” Kirk-Othmer Encyclopedia of Chemical Technology, Vol. 8, 4th Ed. (1992), pp. 223 to 237, the disclosure of which is totally incorporated herein by reference) may also be used. These carboxylic acids may be reacted with alcohols equipped with UV curable moieties to form reactive esters. Examples of these alcohols include 2-allyloxyethanol from Sigma-Aldrich Co.;

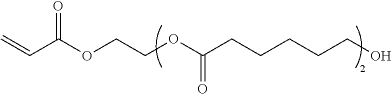

SR495B from Sartomer Company, Inc.;

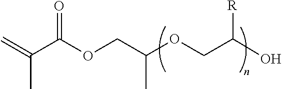

CD572 (R═H, n=10) and SR604 (R=Me, n=4) from Sartomer Company, Inc.

In embodiments, the optional curable wax is included in the composition in an amount of from, for example, about 1 to about 25% by weight of the composition, such as from about 2 to about 20% by weight of the composition, or from about 2.5 to about 15% by weight of the composition.

The curable monomer or prepolymer and curable wax together may form more than about 50% by weight of the composition, or at least 70% by weight of the composition, or at least 80% by weight of the composition.

Gellant

The object-forming composition may comprise one or more gellants. Suitable gellants include a curable gellant comprised of a curable amide, a curable polyamide-epoxy acrylate component and a polyamide component; a curable composite gellant comprised of a curable epoxy resin and a polyamide resin; mixtures thereof and the like, as disclosed in U.S. Patent Application Publication No. 2010/0304040, the disclosure of which is hereby incorporated herein by reference in its entirety. Inclusion of the gellant in the composition permits the composition to be applied over a substrate, such as on one or more portions of the substrate, without excessive penetration into the substrate because the viscosity of the composition is quickly increased as the composition cools following application. The curable gellant may also participate in the curing of monomer(s) of the composition.

The gellants may be amphiphilic in nature to improve wetting when the composition is used over a substrate having silicone or other oil thereon. “Amphiphilic” refers to molecules that have both polar and non-polar parts of the molecule. For example, the gellants may have long non-polar hydrocarbon chains and polar amide linkages.

Amide gellants include those described in U.S. Patent Application Publication No. 2008/0122914 and U.S. Pat. Nos. 7,276,614 and 7,279,587, the entire disclosures of which are incorporated herein by reference.

The amide gellant may be a compound of the following formula (I):

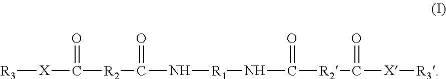

In formula (I), may be:

(i) an alkylene group (wherein an alkylene group is a divalent aliphatic group or alkyl group, including linear and branched, saturated and unsaturated, cyclic and acyclic, and substituted and unsubstituted alkylene groups; and wherein heteroatoms, such as oxygen, nitrogen, sulfur, silicon, phosphorus, boron, and the like either may or may not be present in the alkylene group) having from about 1 to about 12 carbon atoms, such as from about 1 to about 8, or from about 1 to about 5 carbon atoms;

(ii) an arylene group (wherein an arylene group is a divalent aromatic group or aryl group, including substituted and unsubstituted arylene groups, and wherein heteroatoms, such as oxygen, nitrogen, sulfur, silicon, phosphorus, boron, and the like either may or may not be present in the arylene group) having from about 1 to about 15 carbon atoms, such as from about 3 to about 10, or from about 5 to about 8 carbon atoms;

(iii) an arylalkylene group (wherein an arylalkylene group is a divalent arylalkyl group, including substituted and unsubstituted arylalkylene groups, wherein the alkyl portion of the arylalkylene group can be linear or branched, saturated or unsaturated, and cyclic or acyclic, and wherein heteroatoms, such as oxygen, nitrogen, sulfur, silicon, phosphorus, boron, and the like either may or may not be present in either the aryl or the alkyl portion of the arylalkylene group) having from about 6 to about 32 carbon atoms, such as from about 6 to about 22, or from about 6 to about 12 carbon atoms; or

(iv) an alkylarylene group (wherein an alkylarylene group is a divalent alkylaryl group, including substituted and unsubstituted alkylarylene groups, wherein the alkyl portion of the alkylarylene group can be linear or branched, saturated or unsaturated, and cyclic or acyclic, and wherein heteroatoms, such as oxygen, nitrogen, sulfur, silicon, phosphorus, boron, and the like either may or may not be present in either the aryl or the alkyl portion of the alkylarylene group) having from about 5 to about 32 carbon atoms, such as from about 6 to about 22, or from about 7 to about 15 carbon atoms.

Unless otherwise specified, the substituents on the substituted alkyl, aryl, alkylene, arylene, arylalkylene, and alkylarylene groups disclosed above and hereinafter may be selected from halogen atoms, cyano groups, pyridine groups, pyridinium groups, ether groups, aldehyde groups, ketone groups, ester groups, amide groups, carbonyl groups, thiocarbonyl groups, sulfide groups, nitro groups, nitroso groups, acyl groups, azo groups, urethane groups, urea groups, mixtures thereof, and the like. Optionally, two or more substituents may be joined together to form a ring.

In formula (I), R₂ and R₂′ each, independently of the other, may be:

(i) alkylene groups having from about 1 to about 54 carbon atoms, such as from about 1 to about 48, or from about 1 to about 36 carbon atoms;

(ii) arylene groups having from about 5 to about 15 carbon atoms, such as from about 5 to about 13, or from about 5 to about 10 carbon atoms;

(iii) arylalkylene groups having from about 6 to about 32 carbon atoms, such as from about 7 to about 33, or from about 8 to about 15 carbon atoms; or

(iv) alkylarylene groups having from about 6 to about 32 carbon atoms, such as from about 6 to about 22, or from about 7 to about 15 carbon atoms.

In formula (I), R₃ and R₃′ each, independently of the other, may be either:

(a) photoinitiating groups, such as groups derived from 1-(4-(2-hydroxyethoxy)phenyl)-2-hydroxy-2-methylpropan-1-one, of the formula (II):

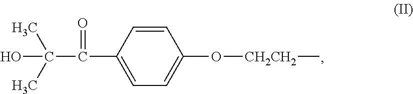

groups derived from 1-hydroxycyclohexylphenylketone, of the formula (III):

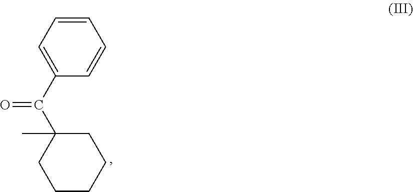

groups derived from 2-hydroxy-2-methyl-1-phenylpropan-1-one, of the formula (IV):

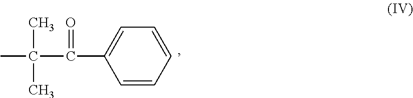

groups derived from N,N-dimethylethanolamine or N,N-dimethylethylenediamine, of the formula (V):

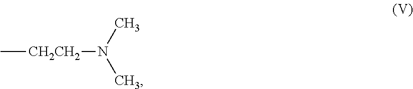

or the like; or

(b) a group which is:

(i) an alkyl group (wherein an alkyl group includes linear and branched, cyclic and acyclic, and substituted and unsubstituted alkyl groups, and wherein hetero atoms such as oxygen, nitrogen, sulfur, silicon, phosphorus, boron, and the like, may optionally be present in the alkyl group) having from about 2 to about 100 carbon atoms, such as from about 3 to about 60, or from about 4 to about 30 carbon atoms;

(ii) an aryl group (wherein an aryl group includes substituted and unsubstituted aryl groups) having from about 5 to about 100 carbon atoms, such as from about 5 to about 60, or from about 6 to about 30 carbon atoms, such as phenyl or the like;

(iii) an arylalkyl group having from about 5 to about 100 carbon atoms, such as from about 5 to about 60, or from about 6 to about 30 carbon atoms, such as benzyl or the like; or

(iv) an alkylaryl group having from about 5 to about 100 carbon atoms, such as from about 5 to about 60, or from about 6 to about 30 carbon atoms, such as tolyl or the like.

In addition, in formula (I), X and X′ each, independently of the other, may be an oxygen atom or a group of the formula —NR₄—, wherein R₄ is:

(i) a hydrogen atom;

(ii) an alkyl group having from about 5 to about 100 carbon atoms, such as from about 5 to about 60 or from about 6 to about 30 carbon atoms;

(iii) an aryl group having from about 5 to about 100 carbon atoms, such as from about 5 to about 60 or from about 6 to about 30 carbon atoms;

(iv) an arylalkyl group having from about 5 to about 100 carbon atoms, such as from about 5 to about 60 or from about 6 to about 30 carbon atoms; or

(v) an alkylaryl group having from about 5 to about 100 carbon atoms, such as from about 5 to about 60 or from about 6 to about 30 carbon atoms.

Further details may be found, for example, in U.S. Pat. Nos. 7,279,587 and 7,276,614.

The gellant may comprise one of or a mixture of formulas (VI), (VII), or (VIII):

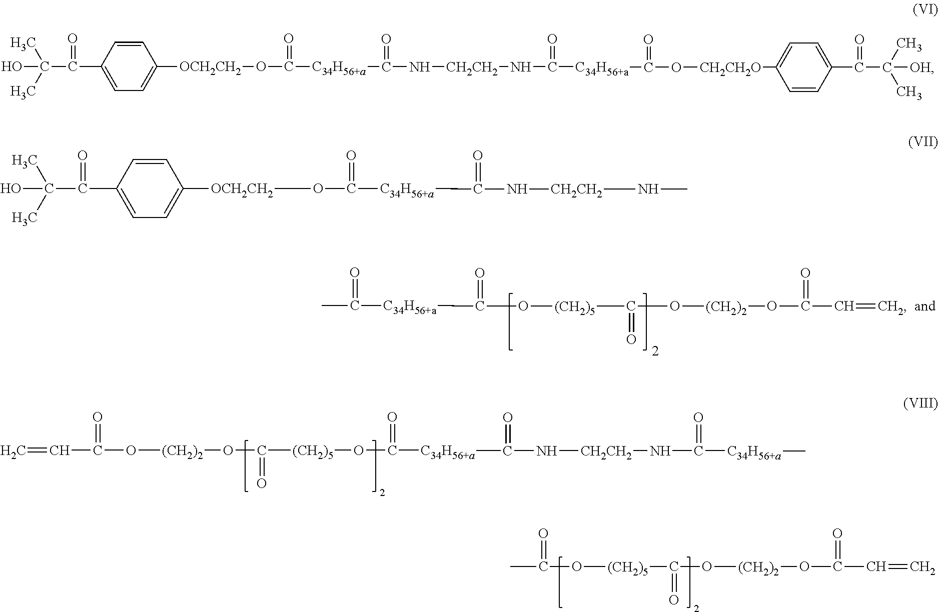

where —C₃₄H₅₆₊ₐ— represents a branched alkylene group that may include unsaturations and cyclic groups, and the variable “a” is an integer from 0-12.

The gellant may be a composite gellant, for example, a gellant comprised of a curable epoxy resin and a polyamide resin. Suitable composite gellants are described in commonly assigned U.S. Pat. No. 7,563,489, the entire disclosure of which is incorporated herein by reference.

The epoxy resin component in the composite gellant may be any suitable epoxy group-containing material. The epoxy group containing component includes the diglycidyl ethers of either polyphenol-based epoxy resin or a polyol-based epoxy resin, or mixtures thereof. That is, the epoxy resin has two epoxy functional groups that are located at the terminal ends of the molecule. The polyphenol-based epoxy resin is a bisphenol A-co-epichlorohydrin resin with not more than two glycidyl ether terminal groups. The polyol-based epoxy resin may be a dipropylene glycol-co-epichlorohydrin resin with not more than two glycidyl ether terminal groups. Suitable epoxy resins have a weight average molecular weight in the range of from about 200 to about 800, such as from about 300 to about 700. Commercially available sources of the epoxy resins are, for example, the bisphenol-A based epoxy resins from Dow Chemical Corp., such as DER 383, or the dipropyleneglycol-based resins from Dow Chemical Corp., such as DER 736. Other sources of epoxy-based materials originating from natural sources may be used, such as epoxidized triglyceride fatty esters of vegetable or animal origins, for example epoxidized linseed oil, rapeseed oil, and the like, or mixtures thereof. Epoxy compounds derived from vegetable oils such as the VIKOFLEX line of products from Arkema Inc., Philadelphia Pa. may also be used. The epoxy resin component is thus functionalized with acrylate or (meth)acrylate, vinyl ether, allyl ether, and the like, by chemical reaction with unsaturated carboxylic acids or other unsaturated reagents. For example, the terminal epoxide groups of the resin become ring-opened in this chemical reaction, and are converted to (meth)acrylate esters by esterification reaction with (meth)acrylic acid.

As the polyamide component of the epoxy-polyamide composite gellant, any suitable polyamide material may be used. The polyamide is comprised of a polyamide resin derived from a polymerized fatty acid such as those obtained from natural sources (for example, palm oil, rapeseed oil, castor oil, and the like, including mixtures thereof) or the commonly known hydrocarbon “dimer acid,” prepared from dimerized C-18 unsaturated acid feedstocks such as oleic acid, linoleic acid, and the like, and a polyamine, such as a diamine (for example, alkylenediamines such as DYTEK series diamines, ethylenediamine, poly(alkyleneoxy)diamines, and the like, or also copolymers of polyamides such as polyester-polyamides and polyether-polyamides. One or more polyamide resins may be used in the formation of the gellant Commercially available sources of the polyamide resin include, for example, the VERSAMID series of polyamides (available from Cognis Corporation (formerly Henkel Corp.)); in particular VERSAMID 335, VERSAMID 338, VERSAMID 795, and VERSAMID 963, all of which have low molecular weights and low amine numbers; and the SYLVAGEL polyamide resins (available from Arizona Chemical Company), and variants thereof including polyether-polyamide resins may be employed. The composition of the SYLVAGEL resins obtained from Arizona Chemical Company are described as polyalkyleneoxydiamine polyamides with the general formula (IX),

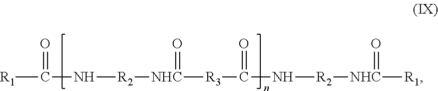

wherein R₁ is an alkyl group having at least seventeen carbon atoms, R₂ includes a polyalkyleneoxide, R₃ includes a C-6 carbocyclic group, and n is an integer of at least 1.

The gellant may also comprise a curable polyamide-epoxy acrylate component and a polyamide component, such as those disclosed in U.S. Pat. No. 7,632,546, the entire disclosure of which is incorporated herein by reference. The curable polyamide-epoxy acrylate is curable by virtue of including at least one functional group therein. As an example, the polyamide-epoxy acrylate is difunctional. The functional group(s), such as the acrylate group(s), are radiation-curable via free-radical initiation and enable chemical bonding of the gellant to the cured ink vehicle. A commercially available polyamide-epoxy acrylate is PHOTOMER RM370 from Cognis. The curable polyamide-epoxy acrylate may also be selected from within the structures described above for the curable composite gellant comprised of a curable epoxy resin and a polyamide resin.

The composition may include the gellant in any suitable amount, such as from about 1 to about 50 wt %, or from about 2 to about 20 wt %, or from about 3 to about 10 wt % of the composition.

The gellant may comprise a compound of the formula (X):

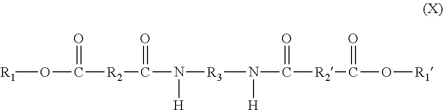

where:

R₁ and R₁′ are the same and are selected from the following non-reactive aromatic groups:

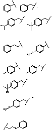

wherein [symbol] represents the point of attachment of the R₁ and R₁′ group.

In some embodiments, R₁ and R₁′ are the same and are selected from the formulas:

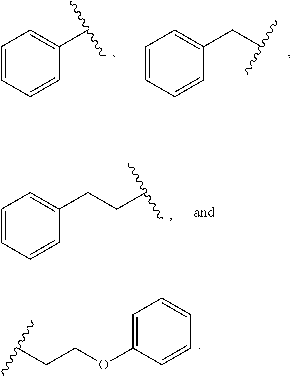 [SMILES: *c1ccccc1 ; *Cc1ccccc1 ; *CCc1ccccc1 ; *CCOc1ccccc1]

In one specific embodiment, R₁ and R₁′ are each of the formula

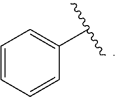 [SMILES: *c1ccccc1]

In another specific embodiment, R₁ and R₁′ are each of the formula

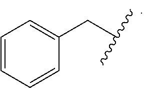 [SMILES: *Cc1ccccc1]

In yet another specific embodiment, R₁ and R₁′ are each of the formula

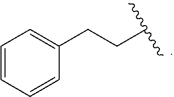 [SMILES: *CCc1ccccc1]

In still another specific embodiment, R₁ and R₁′ are each of the formula

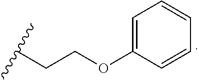 [SMILES: *CCOc1ccccc1]

R₂ and R₂′ are the same or different, and are each independently selected from:

(i) alkylene groups having from about 2 to about 100 carbon atoms, such as at least about 2, 4, 6, 8, 10, 12, 14, 16, 18, 20, 22, 24, 26, 28, 30, 32, 34, or 36 carbon atoms, or no more than about 100, or no more than about 60, or no more than about 50 carbon atoms, or such as having about 36 carbon atoms;

(ii) arylene groups having from about 5 to about 100 carbon atoms, such as, for example, at least about 5 or 6 carbon atoms, or no more than about 100, or no more than about 60, or no more than about 50 carbon atoms;

(iii) arylalkylene groups having from about 6 to about 100 carbon atoms, such as, for example, at least about 6 or 7 carbon atoms, or nor more than about 100, or no more than about 60, or no more than about 50 carbon atoms; and

(iv) alkylarylene groups having from about 6 to about 100 carbon atoms, such as, for example, at least 6 or 7 carbon atoms, or no more than about 100, or no more than about 60, or no more than about 50 carbon atoms.

In some embodiments, R₂ and R₂′ are both alkylene groups, which can be linear or branched, saturated or unsaturated, cyclic or acyclic, and substituted alkylene groups, and hetero atoms may optionally be present in the alkylene group. In some other embodiments, R₂ and R₂′ are both saturated alkylene groups. In other embodiments, R₂ and R₂′ are both unsubstituted alkylene groups. In some embodiments, R₂ and R₂′ are each of the formula

—C₃₄H_{56+a—}

and are branched alkylene groups that may include unsaturations and cyclic groups, where a is an integer of 0, 1, 2, 3, 4, 5, 6, 7, 8, 9, 10, 11, or 12. In some other embodiments, R₂ and R₂′ include isomers of the formula

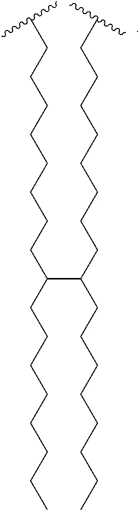 [SMILES: *CCCCCCCCC(CCCCCCCC)C(CCCCCCCC)CCCCCCCC*]

R₃ is:

(i) an alkylene group having from about 2 to about 80 carbon atoms, such as, for example, at least about 2 carbon atoms, or no more than about 80, 60, 50, or 36 carbon atoms;

(ii) an arylene group having from about 2 to about 50 carbon atoms, such as, for example, about 2 carbon atoms, or having no more than about 5 or 6 carbon atoms, or no more than about 50, 25, or 18 carbon atoms;

(iii) an arylalkylene group having from about 6 to about 50 carbon atoms such as, for example, at least about 6 or 7 carbon atoms, or no more than about 50, 36, or 18 carbon atoms; or

(iv) an alkylarylene group having from about 6 to about 50 carbon atoms, such as, for example, at least about 6 or 7 carbon atoms, or no more than about 50, 36, or 18 carbon atoms.

In some embodiments, R₃ is a linear or branched alkylene group, which can be saturated or unsaturated, substituted or unsubstituted alkylene groups, and where hetero atoms may optionally be present in the alkylene group. In a specific embodiment, R₃ is an ethylene group

—CH₂CH₂—.

In embodiments where R₁ and R₁′ are a single species end-capping both ends of the gellant compound, a single gellant product is provided, rather than a mixture, thereby eliminating the need for complex post-reaction purification and processing. The gellant composition functionalized with identical aromatic end-cap molecules provides enhanced spectral transmission and gelation properties, such as reduced ultraviolet absorbance, higher thermal stability, and higher ultimate viscosity over prior gellant compounds.

Aromatic end-capped gellant compounds have reduced ultraviolet absorbance that enables more efficient ultraviolet cure of the composition. In certain embodiments, the compounds herein provide an absorbance of from about 0 to about 0.8, or from about 0 to about 0.7, or from about 0 to about 0.6 at a wavelength of from about 230 to about 400 nanometers.

In embodiments where R₁ and R₁′ are the same non-reactive end-cap molecule, the resultant gellant compound exhibits high thermal stability. With respect to thermal stability, heating of a conventional gellant overnight in an oven at 85° C. yields a product that is incompletely soluble in monomer. In embodiments herein, gellants with aromatic end-cap functionality are stable for at least about 8 weeks in an oven at 85° C. and the material is freely soluble in monomer. As used here, “stable” means that there is no crosslinking or decomposition of the gellant material, and it remains completely soluble in monomer. The use of a single end-cap species results in cleaner product synthesis with fewer side products.

In certain embodiments, the compounds herein provide a complex viscosity of from about 10⁴ centipoise (cP) to about 10⁸ cP, or from about 10⁵ cP to about 10⁷ cP, or from about 10⁵ cP to about 10⁶ cP at a temperature of from about 10° C. to about 50° C.

Specific gellant compounds may be of one of the following formulas:

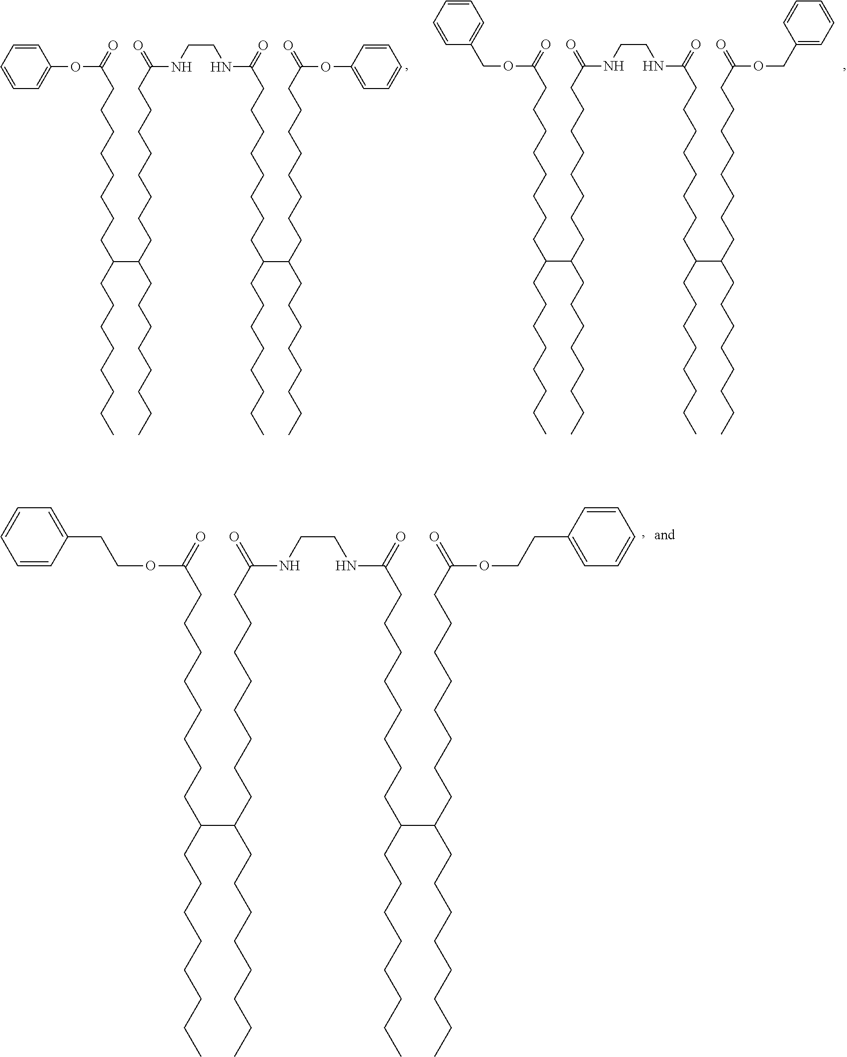 [SMILES: CCCCCCCCC(CCCCCCCCC(=O)NCCNC(=O)CCCCCCCCC(CCCCCCCC)C(CCCCCCCC)CCCCCCCCC(=O)Oc1ccccc1)C(CCCCCCCC)CCCCCCCCC(=O)Oc1ccccc1 ; CCCCCCCCC(CCCCCCCCC(=O)NCCNC(=O)CCCCCCCCC(CCCCCCCC)C(CCCCCCCC)CCCCCCCCC(=O)OCc1ccccc1)C(CCCCCCCC)CCCCCCCCC(=O)OCc1ccccc1 ; CCCCCCCCC(CCCCCCCCC(=O)NCCNC(=O)CCCCCCCCC(CCCCCCCC)C(CCCCCCCC)CCCCCCCCC(=O)OCCc1ccccc1)C(CCCCCCCC)CCCCCCCCC(=O)OCCc1ccccc1]

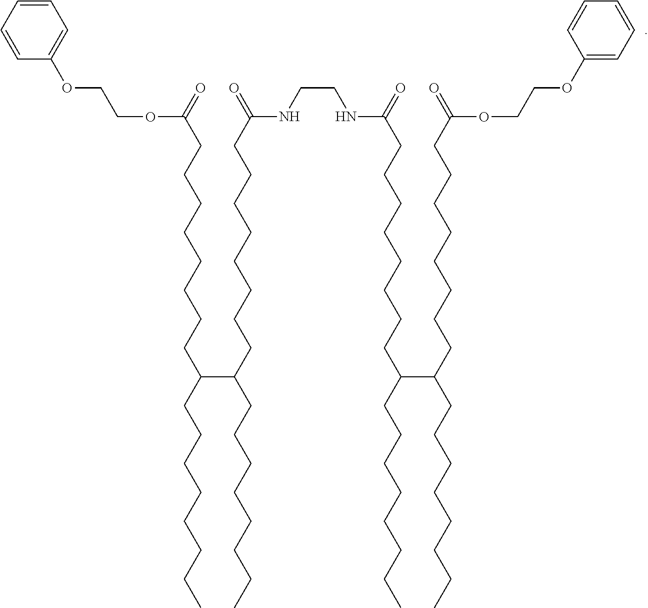 [SMILES: CCCCCCCCC(CCCCCCCCC(=O)NCCNC(=O)CCCCCCCCC(CCCCCCCC)C(CCCCCCCC)CCCCCCCCC(=O)OCCOc1ccccc1)C(CCCCCCCC)CCCCCCCCC(=O)OCCOc1ccccc1]

The gellant may comprise a compound of the formula (XI):

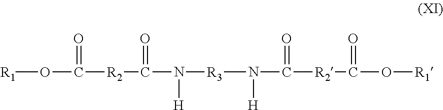

where R₂, R₂′ and R₃ are as described above for formula (X), and R₁ and R₁′ can be the same or different, and each, independently of the other, is:

(i) an alkyl group having a least one ethylenic unsaturation therein and having at least about 2, 3, or 4 carbon atoms, or no more than about 100, 60, or 30 carbon atoms;

(ii) an arylalkyl group having at least one ethylenic unsaturation therein, and having from about 6 to about 100 carbon atoms, such as, for example, at least about 6 or 7 carbon atoms, or no more than about 100, 60, or 30 carbon atoms;

(iii) an alkylaryl group having at least one ethylenic unsaturation therein, having about 6 to about 100 carbon atoms, such as at least about 6 or 7 carbon atoms, or not more than about 100, 60, or 30 carbon atoms; or

(iv) a non-reactive aromatic group;

provided that at least one of R₁ and R₁′ is a non-reactive aromatic group, and provided that neither of R₁ or R₁′ is a photoinitiator group.

One of R₁ or R_{1′} may be selected from the following formulas:

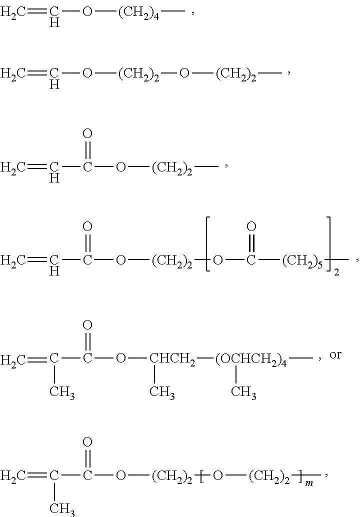

where “m” is an integer representing the number of repeating (O—(CH₂)₂ units. The variable “m” may be an integer from 1 to 10, or “m” may be an integer greater than 10,

Specific examples of suitable gellant compounds include the following formulas:

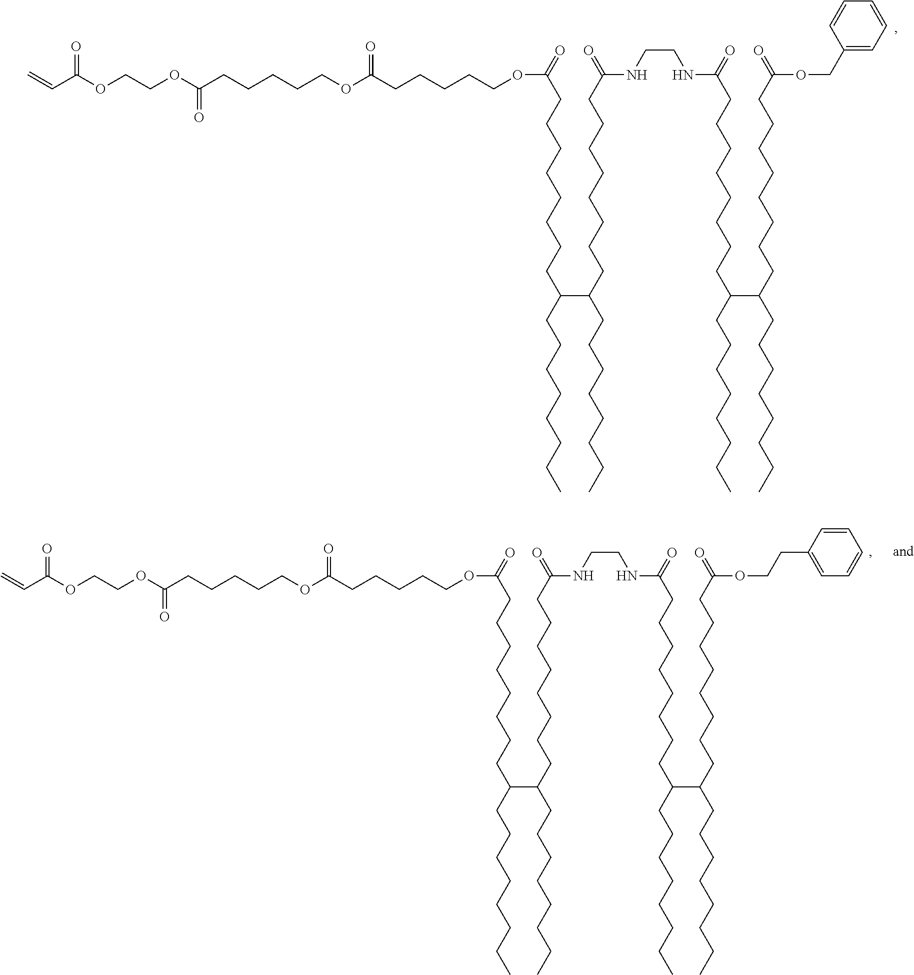 [SMILES: C=CC(=O)OCCOC(=O)CCCCCOC(=O)CCCCCOC(=O)CCCCCCCCC(CCCCCCCC)C(CCCCCCCC)CCCCCCCCC(=O)NCCNC(=O)CCCCCCCCC(CCCCCCCC)C(CCCCCCCC)CCCCCCCCC(=O)OCc1ccccc1 ; C=CC(=O)OCCOC(=O)CCCCCOC(=O)CCCCCOC(=O)CCCCCCCCC(CCCCCCCC)C(CCCCCCCC)CCCCCCCCC(=O)NCCNC(=O)CCCCCCCCC(CCCCCCCC)C(CCCCCCCC)CCCCCCCCC(=O)OCCc1ccccc1]

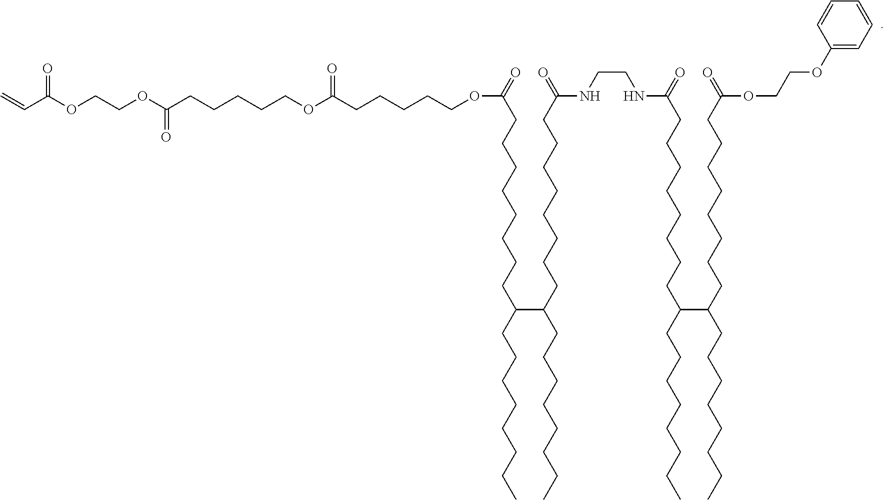 [SMILES: C=CC(=O)OCCOC(=O)CCCCCOC(=O)CCCCCOC(=O)CCCCCCCCC(CCCCCCCC)C(CCCCCCCC)CCCCCCCCC(=O)NCCNC(=O)CCCCCCCCC(CCCCCCCC)C(CCCCCCCC)CCCCCCCCC(=O)OCCOc1ccccc1]

### Examples

A silver nanoparticle ink composed of dodecylamine stabilized silver nanoparticles dispersed in decalin solvent at 40 wt % loading was prepared.

The following object-forming composition (UV-gel ink) was prepared:

| Component | wt % | m/g |
|---|---|---|
| Amide gellant (PP-Agel-8) | 7.5 | 15.00 |
| Unilin 350-acrylate (PP- | 5.0 | 10.00 |
| U350Ac-5) | | |
| SR9003 | 67.8 | 135.60 |
| SR399LV | 5.0 | 10.00 |
| Octadecyl Acrylate | 10.0 | 20.00 |
| Irgaeure 819 | 1.0 | 2.00 |
| Irgacure 127 | 3.5 | 7.00 |
| Irgastab UV10 | 0.2 | 0.40 |
| TOTAL | 100.0 | 200.00 |

A piece of Mylar was taped to the drum of a TUV (Typhoon printer modified for UV ink printing). The object-forming composition layer was built up in 45 sequential revolutions, jetted at 85 degrees. The thickness was about 0.475 mm. The resulting 3-D printed structures were cured at 32 rpm using a Fusions UV 600 W lamp fitted with a D bulb.

The silver nanoparticle ink was inkjet printed on top of the three-dimensional structures formed with the object-forming composition. The silver nanoparticle ink was deposited using DIMATIX DMP-2800 inkjet printer equipped with 10 μL cartridge, with a drop spacing of 20 μm. A straight line was printed on top of a structure and printed over the structure onto the substrate. The printed line was thereafter annealed in an oven at 120° C. for 10 min. After cooling down to room temperature, the resistance was measured. The resistance was measured as low as 5-6 ohms for 1 mm line, which is in line with the resistance measured for silver lines printed on glass or PET substrate.

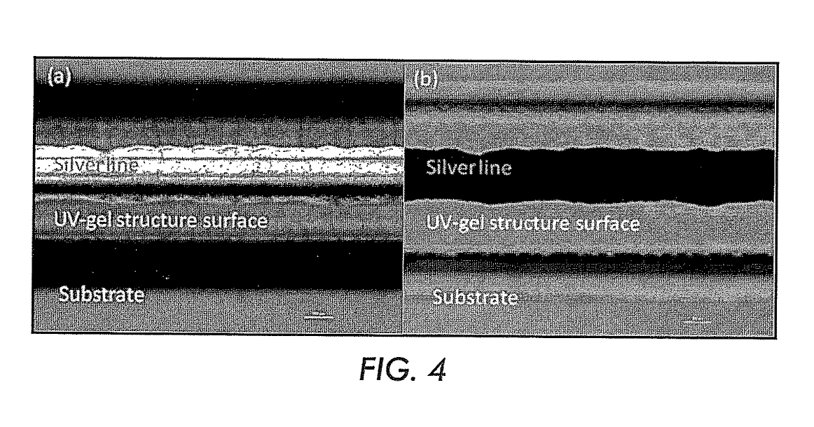

FIG. 4 is an optical image of a printed and annealed silver line on top of a UV-gel ink structure in both reflection and transmission modes. In reflection mode, a white silver line on top of clear UV-gel structure is shown. Due to the 3-D shape, the substrate is out of focus. In transmission mode, a black line was observed since both PET substrate and UV-gel ink are clear while the silver line blocked the light.

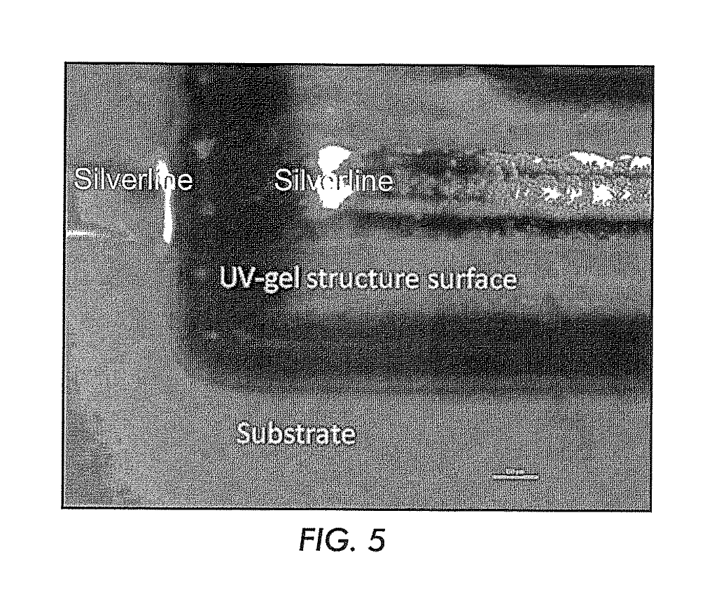

The silver nanoparticle ink could run over the edge of the 3-D UV-gel structure to form a continuous and conductive line, although the UV-gel structure had a height of about 300 μm. FIG. 5 is an optical image of a silver line run over a UV-gel structure onto a substrate. A resistance of 6000 ohms was detected over the edge area, indicating the line is continuous over a height of 300 um. It is expected that the resistance can be reduced by optimizing the thickness of silver line, the edge smoothness of the 3-D structure, printing conditions, etc.

It will be appreciated that various of the above-disclosed and other features and functions, or alternatives thereof, may be desirably combined into many other different systems or applications. Also, various presently unforeseen or unanticipated alternatives, modifications, variations or improvements therein may be subsequently made by those skilled in the art, and are also intended to be encompassed by the following claims.

1. A method of forming a conductive feature on a non-planar three-dimensional object, comprising:
producing the three-dimensional object by a process that includes:
depositing an object-forming composition to form layers on portions of a substrate, the object-forming composition comprising a monomer, photoinitiator, a wax, and a gellant; and
curing the object-forming composition;
depositing a metal nanoparticle composition onto a non-planar portion of the three-dimensional object, the metal nanoparticle composition comprising metal nanoparticles in a dispersing solvent and the non-planar portion having a varying height; and
annealing the composition to form the conductive feature,
wherein the conductive feature has a resistance of from 2 to 10,000 ohms.

2. (canceled)

3. The method of claim 1, wherein the metal nanoparticles are stabilized silver nanoparticles.

4. The method of claim 3, wherein the stabilized silver nanoparticles have a stabilizer selected from the group consisting of methylamine, ethylamine, propylamine, butylamine, pentylamine, hexylamine, heptylamine, octylamine, nonylamine, decylamine, hexadecylamine, undecylamine, dodecylamine, tridecylamine, tetradecylamine, diaminopentane, diaminohexane, diaminoheptane, diaminooctane, diaminononane, diaminodecane, diaminooctane, dipropylamine, dibutylamine, dipentylamine, dihexylamine, diheptylamine, dioctylamine, dinonylamine, didecylamine, methylpropylamine, ethylpropylamine, propylbutylamine, ethylbutylamine, ethylpentylamine, propylpentylamine, butylpentylamine, tributylamine, trihexylamine and mixtures thereof.

5. The method of claim 1, wherein the metal nanoparticle composition further comprises a gellant.

6. (canceled)

7. The method of claim 1, wherein the metal nanoparticle composition is deposited by printing.

8. The method of claim 7, wherein the object-forming composition is deposited by printing.

9. The method of claim 1, wherein the metal nanoparticle composition is deposited onto the non-planar portion of the three-dimensional object to form a layer having a thickness of from about 0.0001 to about 6 mm.

10. The method of claim 1, wherein the metal nanoparticle composition is deposited as more than one layer and on more than one portion of the three-dimensional object.

11. The method of claim 1, wherein the conductive feature has a conductivity of more than about 10 S/cm.

12. (canceled)

13. The method of claim 1, wherein the conductive feature is at least a portion of a conductive line, a conductive trace, a conductive via, a conductive pad, an electrode, or a capacitor.

14. (canceled)

15. The method of claim 1, wherein the conductive feature varies in height as a result of the metal nanoparticle composition being deposited on the non-planar portion of the three-dimensional object and has conductivity throughout the conductive feature.

16. A method of forming a conductive feature on a three-dimensional object, comprising:
printing a contiguous line of a metal nanoparticle composition directly on a non-planar portion of the three-dimensional object, the metal nanoparticle composition comprising metal nanoparticles in a dispersing solvent and the non-planar portion having a varying height; and
heating the contiguous line of the metal nanoparticle composition to form a conductive feature,
wherein:
the conductive feature has conductivity throughout the contiguous line directly on the non-planar portion of the three-dimensional object and has a resistance of from 2 to 10,000 ohms; and
the metal nanoparticles are stabilized with an alkylamine selected from the group consisting of methylamine, ethylamine, propylamine, butylamine, pentylamine, hexylamine, heptylamine, octylamine, nonylamine, decylamine, hexadecylamine, undecylamine, dodecylamine, tridecylamine, tetradecylamine, diaminopentane, diaminohexane, diaminoheptane, diaminooctane, diaminononane, diaminodecane, diaminooctane, dipropylamine, dibutylamine, dipentylamine, dihexylamine, diheptylamine, dioctylamine, dinonylamine, didecylamine, methylpropylamine, ethylpropylamine, propylbutylamine, ethylbutylamine, ethylpentylamine, propylpentylamine, butylpentylamine, tributylamine, trihexylamine and mixtures thereof.

17. The method of claim 16, wherein the method is performed more than once to form a plurality of conductive features on the three-dimensional object.

18. The method of claim 16, wherein the conductive feature is a component or wire of an electronic circuit.

19. The method of claim 16, wherein printing is performed by ink jetting.

20. The method of claim 16, wherein heating is performed at a temperature from about 80° C. to about 250° C.

21. (canceled)

22. The method of claim 1, wherein the gellant is an amide gellant of formula (I): 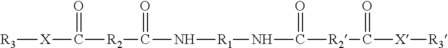
where R₁ represents an alkylene group having from 1 to 12 carbons, an arylene group having from 1 to 15 carbon atoms, an arylalkylene group having from 6 to 32 carbon atoms, or an alkylarylene group having from 5 to 32 carbon atoms;
each R₂ and R₂′ independently represents an alkylene group having from 1 to 54 carbon atoms, an arylene group having from 5 to 15 carbon atoms, an arylalkylene group having from 6 to 32 carbon atoms, or an alkylarylene group having from 6 to 32 carbon atoms;
each R₃ and R₃′ independently represents a photoinitiating group or a group selected from the group consisting of an alkyl group having from 2 to 100 carbon atoms, an aryl group having from 5 to 100 carbon atoms, an arylalkyl group having from 5 to 100 carbon atoms, and an alkylaryl group having from 5 to 100 carbon atoms; and
each X and X′ independently represents an oxygen atom or a group of the formula —NR₄—, wherein R₄ is selected from the group consisting of a hydrogen atom, an alkyl group having from 5 to 100 carbon atoms, an aryl group having from 5 to 100 carbon atoms, an arylalkyl group having from 5 to 100 carbon atoms, and an alkylaryl group having from 5 to 100 carbon atoms.

23. The method of claim 16, wherein the contiguous line is printed so as to traverse an edge present on the non-planar portion of the three-dimensional object.
